(19) United States
(12) Patent Application Publication
(10) Pub. No.: US 2011/0190916 A1
(43) Pub. Date: Aug. 4, 2011

(54) System and Method for Management of Parameters Using Options and Variants in a Product Lifecycle Management System

(75) Inventors: Sanjay Maneklal Patel, Canton, MI (US); Kaushal Patankar, Pune (IN); Ashok Sivaram, Troy, MI (US); William Hinton, Sterling Heights, MI (US)

(73) Assignee: Siemens Product Lifecycle Managemet Software Inc., Plano, TX (US)

(21) Appl. No.: 12/696,160

(22) Filed: Jan. 29, 2010

(51) Int. Cl. G06F 17/50

(52) U.S. Cl. 700/103

(57) ABSTRACT

A system, method, and computer program product for managing parameters in a product lifecycle management data processing system. A method includes creating a variant-specific project from a master dictionary, where the variant-specific project includes a plurality of parameter value objects. The method includes identifying a required parameter value corresponding to a first parameter value object, and assigning a task to a user to provide the required parameter value. The method includes receiving the required parameter value and storing the parameter value in the first parameter value object.

### TECHNICAL FIELD

The present disclosure is directed, in general, to systems and methods for use in computer-aided design, manufacturing, engineering, modeling, and visualization (individually and collectively, “CAD” and “CAD systems”) and in product lifecycle management (“PLM”) systems.

### BACKGROUND OF THE DISCLOSURE

Many manufactured products are first designed and modeled in CAD systems, and PLM systems are used my manufacturers, retailers, customer, and other users to manage the design, use, and disposal of various products. Improved systems are desirable.

### SUMMARY OF THE DISCLOSURE

Various embodiments include a system, method, and computer program product for managing parameters in a product lifecycle management data processing system. A method includes creating a variant-specific project from a master dictionary, where the variant-specific project includes a plurality of parameter value objects. The method includes identifying a required parameter value corresponding to a first parameter value object, and assigning a task to a user to provide the required parameter value. The method includes receiving the required parameter value and storing the parameter value in the first parameter value object.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 depicts a block diagram of a data processing system in which an embodiment can be implemented;

FIG. 2 depicts a flowchart of a process in accordance with a disclosed embodiment; and

FIG. 3 depicts a simplified block diagram in accordance with disclosed embodiments.

### DETAILED DESCRIPTION

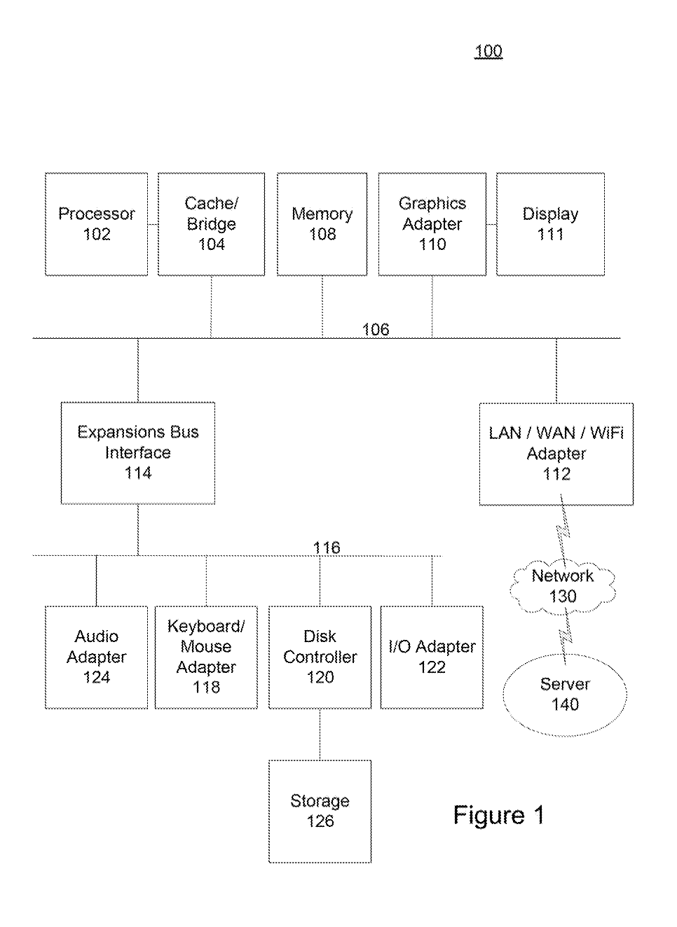

FIGS. 1 through 3 discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Definitions: Following are short definitions of the usual meanings of some of the technical terms which are used in the present application. (However, those of ordinary skill will recognize whether the context requires a different meaning.) Additional definitions can be found in the standard technical dictionaries and journals.

Parameter refers to the embedded system configurable data which is used to enable different behavior using same embedded system software for the different embedded system variants.

Parameter Value refers to value of the embedded system parameter which gets placed on a specific memory address on the embedded system's hardware. Based on this value, the embedded system software provides different functionality for different embedded system variants.

Various embodiments include a system and method for managing embedded software parameter definitions and parameter values.

The disclosed embodiments avoiding the common problem of merging parameter values across various variants of the embedded system when several users who set values deliver them for usage in the embedded system. Currently customers use tools which do not have any access control, configuration capabilities, ability to manage reuse and in some cases are manually created using spreadsheets. The same spreadsheets are delivered to several users asking them to specify values for the given rows for specific columns. Once values are specified the user delivers the files back to the requestor who then merges the values. This process is very time consuming and error prone.

Disclosed embodiments enable users to manage the change process to the parameter definitions used to build templates/dictionaries. The system can also create projects by instantiating the templates. The system can assign tasks to users to collect the values and receive the values from the users to be used in a project. The system automatically assigns and stores the values for the given variant, and stores it. There is no manual merging involved and the value requestor can configure the embedded system by retrieving the required values for a given variant based on an option and variant specification.

Customers will benefit from the disclosed systems by saving time and avoiding errors which cause costly product repairs.

FIG. 1 depicts a block diagram of a data processing system in which an embodiment can be implemented, as a CAD or PLM system that manages parameters as described herein. The data processing system depicted includes a processor 102 connected to a level two cache/bridge 104, which is connected in turn to a local system bus 106. Local system bus 106 may be, for example, a peripheral component interconnect (PCI) architecture bus. Also connected to local system bus in the depicted example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, etc.

Those of ordinary skill in the art will appreciate that the hardware depicted in FIG. 1 may vary for particular implementations. For example, other peripheral devices, such as an optical disk drive and the like, also may be used in addition or in place of the hardware depicted. The depicted example is provided for the purpose of explanation only and is not meant to imply architectural limitations with respect to the present disclosure.

A data processing system in accordance with an embodiment of the present disclosure includes an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100.

Disclosed embodiments include systems and methods that manage the embedded software parameter definition and parameter value setting process. Disclosed embodiments enable multiple users to set values and deliver them to the system for storage and use in product lifecycle management and CAD processes.

The systems stores the parameters in a dictionary, for example in memory 108 or storage 126, or remotely on a server 140, which serves as template for subsequent usage and creation of embedded system projects. The system instantiates the dictionary to act as the integration point for all delivered parameter values. The parameter values can be associated to the correct variants for given projects to avoid common parameter values merging problems.

The disclosed systems enable user to centrally manage the change process to the parameter definitions. The system uses these to build templates and/or dictionaries and to create projects by instantiating the templates. Users can be assigned tasks to collect the values. When the values are received from a user to be used in a project, the values are automatically assigned to the given variant of the embedded system. There is no manual merging involved and a value requestor can configure the embedded system using an options and variant capability to get the required values for a given variant.

The disclosed embodiments provide the user with a very simple and guided interface with which to view the specification details of the parameters as they exist in the particular Master dictionary that was used to instantiate the project and specify values that conform to the specifications set by the owner of the parameters. This way the values can be optimized but cannot be invalid in context of the specifications.

Customers will benefit from this innovation in not only saving time, but avoid errors which cause costly product repairs and recalls. The parameter management and value setting process can be tracked using a change control process, and parameters/dictionaries can be reused across multiple systems. This provides an efficient way to do traceability of the parameters to the functions for which they are introduced as well as to the embedded system binaries in which they are used.

The system stores parameter definitions in a database “dictionary” where the specification/constraint information for the parameter is managed. The dictionary can be instantiated to create projects by which the variability of the embedded system can be managed. The disclosed systems provide a unique solution to solve the complex parameter value setting process for different variants of embedded systems. The system can also track the functions for which parameters are introduced and track changes to the parameters and their values.

The system can interact with a user to create Parameter Definition objects of specific data types. Parameter Definition object creation supports single value, simple array values and also the two dimensional array values. The Parameter Definition can include a number of different datatypes, including but not limited to integer, date, double, string, logical, hex, binary-coded decimal (BCD), and string. To create a Parameter Definition, the inputs can include the name, type and attribute values, if any, and the output is a Parameter Definition to be stored in the master dictionary.

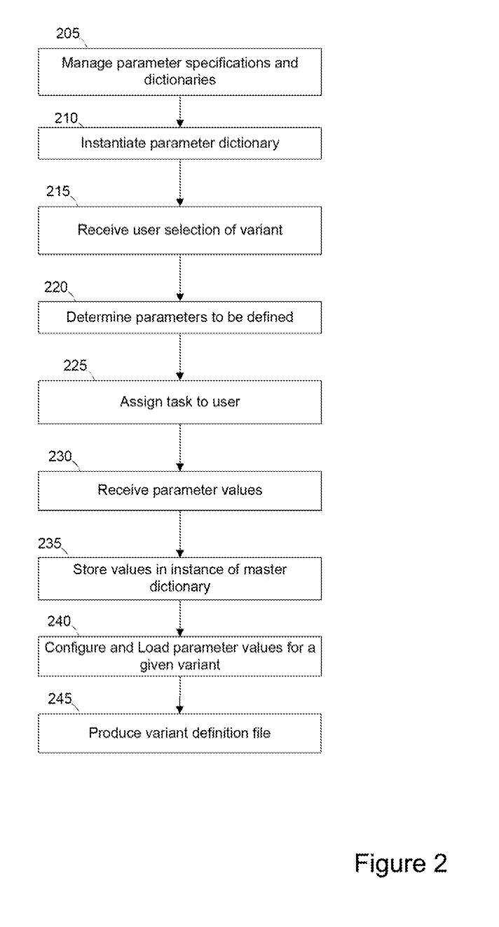

FIG. 2 depicts a flowchart of a process in accordance with a disclosed embodiment.

The systems manages parameter specifications and parameter dictionaries (step 205). Parameter dictionaries can also be used as templates in various embodiments. In some embodiments, the system maintains a master dictionary that includes the parameter definitions for multiple variants and related groups, as described below. The master dictionary may store other data as well in a more comprehensive database of variant data.

In the process of creating a new part, product, or variant (all of these referred to generally as a variant), the system instantiates a parameter dictionary (step 210). In some embodiments, this includes creating a copy of the master parameter dictionary to use for the variant being created. The master dictionary can be instantiated, in some embodiments, by receiving a user selection of all parameter definitions or only the parameter definitions that are required for the project. Project-specific architectural breakdowns, such as breakdowns consisting of subsets of group definitions from the master dictionary, can have their own “variability” derived from the global options.

The system receives a user selection of a variant to be defined (step 215). The system also receives user selection from the parameter dictionary, indicating which parameters must be included in the given variant (step 220). The system assigns a task to a user to define one or more parameter values of the parameters to be defined (step 225). The assignment may be implemented by a direct user interaction, by transmitting the task to a user over a network, or otherwise.

A Product Variant object, in various embodiments, captures the context and configuration of the product for which it is valid, and serves as a container for grouping together the various Product Variant Intents created against specific Product Intents. The Product Variant Object is used to group together various structure context objects which reference the instantiated dictionary representations. Parameter Value objects store the values for each parameter in a Value Group object.

The system receives the parameter values in response to the task assignment (step 230). The system stores the parameter values in the master dictionary as associated with the specific variant (step 235).

Once created, a parameter definition may need to hold different values. For example: the minimum or the maximum values may require a change based on findings from some earlier issues. In such cases, the system enables users to make changes to existing parameter definitions. Users can update parameter definitions by means of modifying them in cases where it is in work-in-progress state or revising it in cases where the existing parameter definition revision is released. This helps the user to maintain the history of changes done to the parameter data.

During a product development process, the system loads the stored parameter values for a particular variant from the instantiation of the master parameter dictionary as used in the given product context (step 240). Using the parameter values, and other PLM or CAD data known to those of skill in the art, the system produces a final variant definition file (step 245), that can be stored and optionally transmitted to another system or user for further processing or manufacture.

The system can also create Definition Groups to group together related Parameter Definitions and also help in defining the parameter master dictionary/template. Generally, the Definition Group object organizes the parameters into various groups based on known usage of related parameters. When creating the Definition Group, users can specify what the object represents. The group could have a number different purposes, including to organizationally group together further groups, parameters and sub-groups in an architecture breakdown, to group together various parameters that are inter-related to, for example, a specific function, and to group together parameters that need to have a specific sequence within a packet. The system can associate Parameter Definition objects to the Definition Group objects. This helps users in organizing the parameters into groups based on the features or commonality of the parameters.

As described above, the system can create a master dictionary of all the Parameter Definitions and with the Definition Groups. In some embodiments, the master dictionary contains the hierarchical layout of all groups across various projects and serves as a template which can be used for instantiating into individual projects. This enables users to carry the definition data into projects so that projects use values that adhere to the specification data.

In some embodiments, the master dictionary structure is implemented as a precise structure. This means that a specific master dictionary revision is associated with specific revisions of the definition groups which themselves are precise. This way a given revision of the master dictionary structure has precisely the revisions of those parameters which are applicable for that revision of the dictionary.

In some embodiments, the system can also maintain a Value Group object. This object has associated Parameter Value objects that store the values for each parameter in the group. The system can thereby enable users to specify values for all the parameters within a group and to attach this object to the Definition Group in the Project-Specific breakdown. A project administrator looking at a specific group definition in the project-specific breakdown can examine the values of all the parameters for that definition group.

The Parameter Value objects that are created when values are received from a user or other system during specification of parameter values for the Definition Group are preferably implementation-specific data model objects which are not directly exposed to the user. Preferably, only the Value Group object that is exposed in the user workspace. Each Value Group object corresponds to a specific Definition Group in a Project specific breakdown. After the Value Group object is created via an interaction with a user, the created Value Group object can be used for specifying as value for all the required projects as long as the corresponding Definition Group Revision in those project-specific elements are same as the Definition Group Revision captured on this value object and which was the source for its creation.

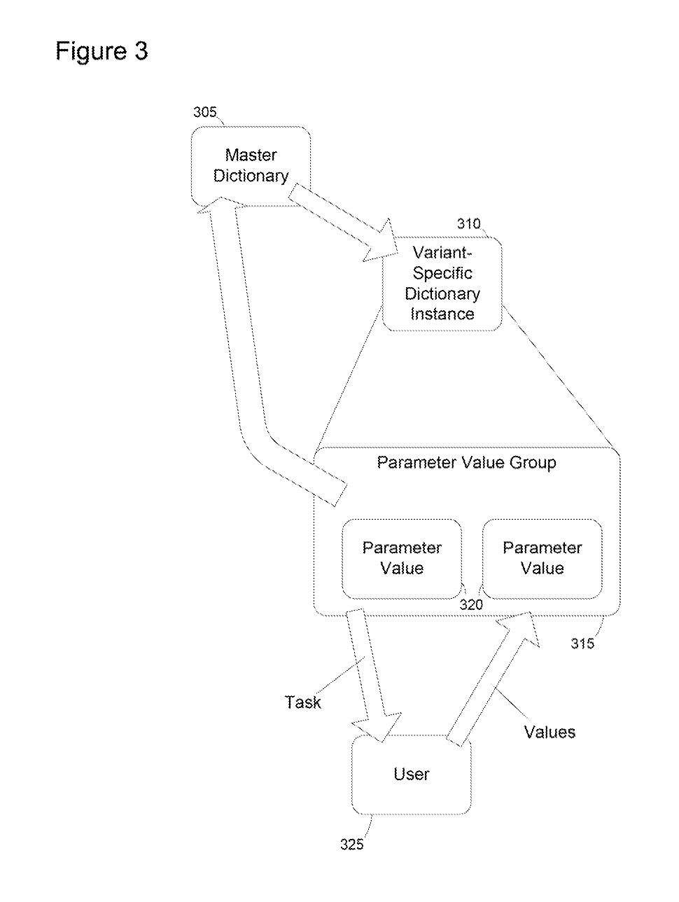

FIG. 3 depicts a simplified block diagram in accordance with disclosed embodiments. As described herein, a master dictionary 305 is instantiated to create a variant-specific project 310.

The variant-specific project 310 includes one or more parameter value groups 315, each of which includes multiple parameter value objects 320.

The system determines which parameter group objects 320 require values, and assigns a task to a user 325 to produce the correct values. The values are received from the user by the system and stored in the parameter value objects 320, which are part of parameter value group 315 of the variant-specific project 310. Because this interaction is specific to the task and the specific parameter value objects for the variant-specific project, there is no parameter merging issue as in conventional systems.

The parameter value group 315, with or without the assigned parameter value objects 230, can then be stored back in the master dictionary 305, with or without the remainder of the variant-specific dictionary 310. When stored as part of the master dictionary 305, the parameter value group 315 is still identified by its specific variant, so it can be reused when the system uses or edits that variant or a derivation of it.

Disclosed embodiments enable parameter management without common problems related to copying, merging of values, reuse and specifying values conforming to parameter specifications. Other embodiments include a structure of parameters that are manually updated for variability and values in an iterative process.

Those skilled in the art will recognize that, for simplicity and clarity, the full structure and operation of all data processing systems suitable for use with the present disclosure is not being depicted or described herein. Instead, only so much of a data processing system as is unique to the present disclosure or necessary for an understanding of the present disclosure is depicted and described. The remainder of the construction and operation of data processing system 100 may conform to any of the various current implementations and practices known in the art.

It is important to note that while the disclosure includes a description in the context of a fully functional system, those skilled in the art will appreciate that at least portions of the mechanism of the present disclosure are capable of being distributed in the form of a instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims. Moreover, none of these claims are intended to invoke paragraph six of 35 USC §112 unless the exact words “means for” are followed by a participle.

What is claimed is:

1. A method for managing parameters in a product lifecycle management data processing system, comprising:
maintaining a master dictionary in a data processing system;
creating a variant-specific project, by the data processing system, from the master dictionary, the variant-specific project including a plurality of parameter value objects;
identifying, by the data processing system, a required parameter value corresponding to a first parameter value object of the plurality of parameter value objects;
assigning a task to a user, by the data processing system, to provide the required parameter value;
receiving the required parameter value by the data processing system; and
storing the parameter value in the first parameter value object.

2. The method of claim 1, wherein the plurality of parameter value objects are stored as part of a parameter value group object.

3. The method of claim 1, wherein the variant-specific project is created by instantiating the master dictionary.

4. The method of claim 1, wherein the first parameter value object, including the parameter value, is also stored in the project created from the master dictionary.

5. The method of claim 1, wherein the data processing system receives a user selection of a variant to be defined.

6. The method of claim 1, wherein a plurality of parameter values are received and stored in the variant-specific project, and the variant-specific project thereby defines a set of parameters specific to a product variant without requiring a parameter merging process.

7. The method of claim 1, wherein the data processing system produces a variant definition file using the stored parameter values.

8. A product lifecycle management data processing system comprising a processor and accessible memory, the data processing system particularly configured to perform the steps of:
creating a variant-specific project from a master dictionary, the variant-specific project including a plurality of parameter value objects;
identifying a required parameter value corresponding to a first parameter value object of the plurality of parameter value objects;
assigning a task to a user to provide the required parameter value;
receiving the required parameter value; and
storing the parameter value in the first parameter value object.

9. The data processing system of claim 8, wherein the plurality of parameter value objects are stored as part of a parameter value group object.

10. The data processing system of claim 8, wherein the variant-specific project is created by instantiating the master dictionary.

11. The data processing system of claim 8, wherein the first parameter value object, including the parameter value, is also stored in the project created from the master dictionary.

12. The data processing system of claim 8, wherein the data processing system receives a user selection of a variant to be defined.

13. The data processing system of claim 8, wherein a plurality of parameter values are received and stored in the variant-specific project, and the variant-specific project thereby defines a set of parameters specific to a product variant without requiring a parameter merging process.

14. The data processing system of claim 8, wherein the data processing system produces a variant definition file using the stored parameter values.

15. A computer-readable storage medium encoded with computer-executable instructions that, when executed, cause a data processing system to perform the steps of:
creating a variant-specific project from a master dictionary, the variant-specific project including a plurality of parameter value objects;
identifying a required parameter value corresponding to a first parameter value object of the plurality of parameter value objects;
assigning a task to a user to provide the required parameter value;
receiving the required parameter value; and
storing the parameter value in the first parameter value object.

16. The computer-readable storage medium of claim 15, wherein the plurality of parameter value objects are stored as part of a parameter value group object.

17. The computer-readable storage medium of claim 15, wherein the variant-specific project is created by instantiating the master dictionary.

18. The computer-readable storage medium of claim 15, wherein the first parameter value object, including the parameter value, is also stored in the project created from the master dictionary.

19. The computer-readable storage medium of claim 15, wherein the data processing system receives a user selection of a variant to be defined.

20. The computer-readable storage medium of claim 15, wherein a plurality of parameter values are received and stored in the variant-specific project, and the variant-specific project thereby defines a set of parameters specific to a product variant without requiring a parameter merging process.

21. The computer-readable storage medium of claim 15, wherein the data processing system produces a variant definition file using the stored parameter values.
